(19) United States
(12) Patent Application Publication
(10) Pub. No.: US 2007/0087569 A1
(43) Pub. Date: Apr. 19, 2007

(54) Method for fabricating semiconductor device

(76) Inventors: Young-Taek Song, Kyoungki-do (KR); Sang-Wook Park, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/479,288

(22) Filed: Jun. 29, 2006

(30) Foreign Application Priority Data
Oct. 18, 2005 (KR) 10-2005-0098204

(51) Int. Cl. H01L 21/461

(52) U.S. Cl. 438/692

(57) ABSTRACT

A method for fabricating a semiconductor device includes forming a plurality of gate patterns over a substrate, each gate pattern comprising a hard mask and a gate electrode, forming a photoresist layer over the gate patterns, performing a planarizing process until the hard masks of the gate patterns are exposed using slurry, and removing the photoresist layer. The hard mask includes an oxide-based material.

### FIELD OF THE INVENTION

The present invention relates to a method for fabricating a semiconductor device, and more particularly, to a method for forming a gate of a semiconductor device with a uniform height.

### DESCRIPTION OF RELATED ARTS

Due to the repetitive deposition and etching of materials performed during a gate pattern formation process for a semiconductor device (e.g., a flash memory device), an overall height of the gates within a wafer becomes irregular when the gates are formed. Consequently, negative effects result with respect to integration of the processes, such as a reduced overlay margin of a photolithography process and a decreased etch target margin.

That is, when an etch-back process is performed, the height of the gates tends to decrease gradually toward edge portions of the wafer when compared to the gates formed on a central wafer portion because of the etching process characteristics. Thus, the irregular height of the gates causes deterioration of the device operational characteristics during subsequent processes.

FIG. 1 illustrates a cross-sectional view to describe a height difference ‘H’ between gates formed during a typical flash memory fabrication process. A plurality of gate patterns G are formed over a substrate 11. Each of the gate patterns G includes a gate electrode 12 and a gate hard mask 13. Since deposition and etching processes are performed to form the gate patterns G, the height of the gate patterns on edge portions tends to be lower than the gate patterns at a central wafer portion because of etching device characteristics used during an etch-back process. The different heights ‘H’ result because a gate etching at the edge portions of the wafer is more actively performed than at the central wafer portion due to the etching device characteristics.

### SUMMARY OF THE INVENTION

It is, therefore, an object of the present invention to provide a method for fabricating a semiconductor device appropriate for forming gates with a uniform height.

In accordance with an aspect of the present invention, there is provided a method for fabricating a semiconductor device, including: forming a plurality of gate patterns over a substrate, each gate pattern comprising a hard mask and a gate electrode; forming a photoresist layer over the gate patterns; performing a planarizing process until the hard masks of the gate patterns are exposed using slurry; and removing the photoresist layer. The hard mask includes an oxide-based material.

### BRIEF DESCRIPTION OF THE DRAWINGS

The above and other objects and features of the present invention will become better understood with respect to the following description of the exemplary embodiments given in conjunction with the accompanying drawings, in which:

FIG. 1 is a cross-sectional view illustrating a method for fabricating a typical flash memory device;

FIGS. 2A and 2B are cross-sectional views illustrating a method for fabricating a semiconductor device (e.g., flash memory device) in accordance with a specific embodiment of the present invention; and

FIGS. 3A to 3C are micrographic views illustrating a method for fabricating a flash memory device in accordance with the specific embodiment of the present invention.

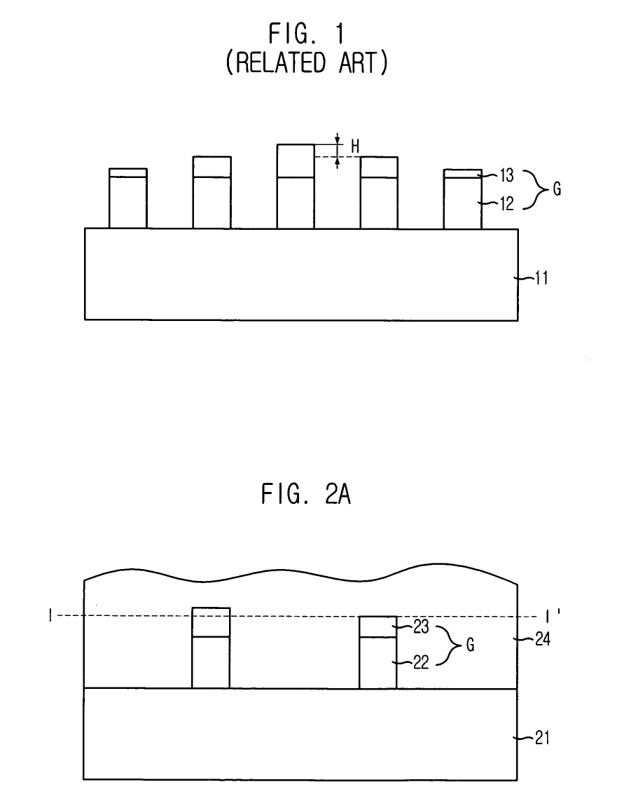

### DETAILED DESCRIPTION OF THE INVENTION

A method for fabricating a semiconductor device in accordance with exemplary embodiments of the present invention will be described in detail with reference to the accompanying drawings.

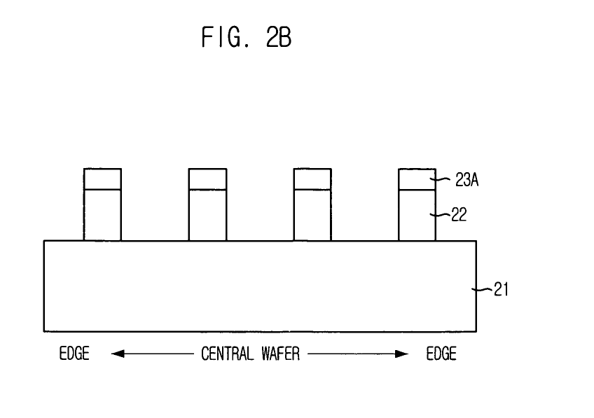

FIGS. 2A and 2B illustrate cross-sectional views to describe a method for fabricating a semiconductor device (e.g., flash memory device) in accordance with a specific embodiment of the present invention.

As shown in FIG. 2A, gate patterns G are formed over a substrate 21. Each of the gate patterns G includes a gate electrode 22 and a gate hard mask 23 formed in sequential order. The gate hard mask 23 includes oxide which has a high selectivity to photoresist. The gate patterns G over the substrate 21 have irregular heights because of deposition and etching processes performed to form the gate patterns G.

A photoresist layer 24 is formed over the gate patterns G and the substrate 21. The photoresist layer 24 is formed to a sufficient thickness to fill spaces between the gate patterns G.

Referring to FIG. 2B, a polishing planarization process, i.e., a chemical mechanical polishing (CMP) process, is performed onto the above substrate structure to obtain the uniform heights of the gate patterns G reaching a perforated line I-I′ as illustrated in FIG. 2A. Also, a polishing selectivity ratio of the photoresist layer 24 to the gate hard mask 23 ranges approximately 50-100:1. Reference numeral 23A denotes planarized gate hard masks.

The planarization process is performed utilizing slurry having a high selectivity between the photoresist layer 24 and the gate hard mask 23 including oxide. Silicon dioxide (SiO₂) slurry in colloid form is used as a polishing agent in the slurry. A primary particle size of SiO₂ ranges from approximately 30 nm to approximately 60 nm, and a secondary particle size of SiO₂ ranges from approximately 70 nm to approximately 100 nm. Furthermore, a concentration of the Sio₂ particles within the slurry ranges from approximately 15 wt % to approximately 20 wt %, and pH of the slurry ranges from approximately 2 to approximately 5. Meanwhile, diluting the slurry can adjust the pH of the slurry. For instance, the slurry can be diluted by adding an aqueous solution having a volume approximately 5 to 10 times higher than the slurry volume.

Moreover, the planarization process is performed by using a mirra device or an EBARA device.

The planarization process using the mirra device is performed by flowing the slurry at approximately 150 ml/min to approximately 250 ml/min under certain conditions. The conditions include: using IC1000 concentric K-Grv on Suba IV (IC1000/SUBAIV) as a pad, which is a marketing product of Rodel Inc. in U.S.; using a membrane pressure ranging from approximately 2 lb to approximately 5 lb; using a retainer ring pressure ranging from approximately 2 lb to approximately 4 lb; using an inner tube pressure ranging from approximately 2 lb to approximately 3 lb; using a platen velocity ranging from approximately 53 rpm to approximately 73 rpm; and using a head velocity ranging from approximately 47 rpm to approximately 67 rpm.

The planarization process using the EBARA device is performed by flowing the slurry at approximately 150 ml/min to approximately 250 ml/min under certain conditions. The conditions include: using IC1000 concentric K-Grv on Suba IV (IC1000/SUBAIV) as a pad, which is a marketing product of Rodel Inc. in U.S.; using a chamber pressure ranging from approximately 200 hPa to approximately 400 hPa; using a retainer ring pressure ranging from approximately 150 lb to approximately 300 lb; using a main air pressure ranging from approximately 350 hPa to approximately 450 hPa; using a central air pressure ranging from approximately 300 hPa to approximately 500 hPa; using a turn table velocity ranging from approximately 53 rpm to approximately 200 rpm; and using a top ring velocity ranging from approximately 47 rpm to approximately 97 rpm.

Although certain products are specified in this embodiment as above, other products may be used in the planarization process.

The CMP process is performed to form the gate patterns uniformly after the photoresist layer 24 is polished and the polishing processes are completed. The CMP process uses a slurry having a high polishing selectivity between the photoresist layer 24 and the gate hard mask 23. An ashing process using an oxygen plasma is employed to strip remaining portions of the photoresist layer 24.

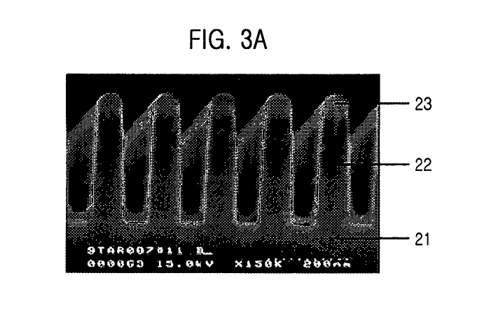

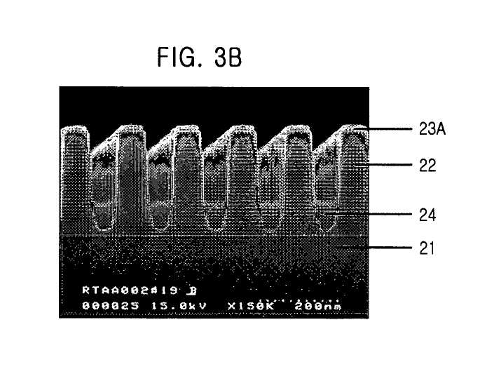

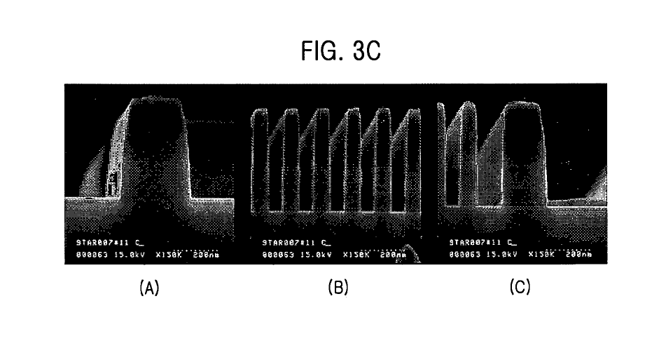

FIGS. 3A to 3C illustrate micrographic views of the substrate structure obtained through the above methods.

FIG. 3A illustrates a micrographic view of the gate patterns formed by performing a gate isolation process. FIG. 3B illustrates a micrographic view of the photoresist layer 24 formed over the substrate 21 and the gate patterns after the planarization process is performed.

Referring to FIG. 3C, reference denotation (A) illustrates a front view of a gate pattern formed in a peripheral region, reference denotation (B) illustrates gate patterns formed in a cell region, and reference denotation (C) illustrates a back view of a gate pattern formed in the peripheral region in accordance with the specific embodiment of the present invention. These views illustrate the uniformity of the height of the gate patterns formed in each region.

In accordance with the specific embodiment of the present invention, by performing the polishing planarization process using the slurry which has a high selectivity between photoresist and oxide, the uniformity of the height of the gates can be improved, and thus, electrical characteristics related to contacts and gates can be improved. Furthermore, a product yield can be increased by improving the electrical characteristics of the device.

The present application contains subject matter related to the Korean patent application No. KR 2005-98204, filed in the Korean Patent Office on Oct. 18, 2005, the entire contents of which being incorporated herein by reference.

While the present invention has been described with respect to certain specific embodiments, it will be apparent to those skilled in the art that various changes and modifications may be made without departing from the spirit and scope of the invention as defined in the following claims.

What is claimed is:

1. A method for fabricating a semiconductor device, the method comprising:
forming a plurality of gate patterns over a substrate, each gate pattern comprising a hard mask and a gate electrode;
forming a photoresist layer over the gate patterns;
performing a planarizing process until the hard masks of the gate patterns are exposed using slurry; and
removing the photoresist layer.

2. The method of claim 1, wherein the polishing selectivity of the photoresist layer to the hard mask ranges approximately 50-100:1.

3. The method of claim 2, wherein the slurry comprises silicon dioxide (SiO₂) in colloid form as a polishing agent.

4. The method of claim 1, wherein the slurry comprises a primary particle having a size ranging from approximately 30 nm to approximately 60 nm, and a secondary particle having a size ranging from approximately 70 nm to approximately 100 nm.

5. The method of claim 1, wherein a concentration of SiO₂ particles in the slurry ranges from approximately 15 wt % to approximately 20 wt %.

6. The method of claim 1, wherein the slurry has a pH level raging from approximately 2 to approximately 5.

7. The method of claim 1, wherein the planarizing process comprises flowing the slurry at approximately 150 ml/min to approximately 250 ml/min using a membrane pressure ranging from approximately 2 lb to approximately 5 lb, a retainer ring pressure ranging from approximately 2 lb to approximately 4 lb, an inner tube pressure ranging from approximately 2 lb to approximately 3 lb, a platen velocity ranging from approximately 53 rpm to approximately 73 rpm, and a head velocity ranging from approximately 47 rpm to approximately 67 rpm.

8. The method of claim 1, wherein the planarizing process comprises flowing the slurry at approximately 150 ml/min to approximately 250 ml/min using a chamber pressure ranging from approximately 200 hPa to approximately 400 hPa, a retainer ring pressure ranging from approximately 150 lb to approximately 300 lb, a main air pressure ranging from approximately 350 hPa to approximately 450 hPa, a central air pressure ranging from approximately 300 hPa to approximately 500 hPa, a turn table velocity ranging from approximately 53 rpm to approximately 200 rpm, and a top ring velocity ranging from approximately 47 rpm to approximately 97 rpm.

9. The method of claim 1, wherein the removing of the photoresist comprises performing an ashing process.

10. The method of claim 1, wherein the hard mask comprises an oxide-based material.

11. The method of claim 1, wherein the forming of the photoresist layer fills spaces between the gate structures.
